(19) United States
(12) Patent Application Publication
(10) Pub. No.: US 2008/0303044 A1
(43) Pub. Date: Dec. 11, 2008

(54) SEMICONDUCTOR LIGHT-EMITTING DEVICE

(75) Inventors: Tatsuoki Kohno, Tokyo (JP); Akiko Suzuki, Tokyo (JP); Shinetsu Fujieda, Kawasaki-shi (JP); Toshihide Takahashi, Tokyo (JP); Hatsuo Takezawa, Yokohama-shi (JP)

Correspondence Address: Charles N.J. Ruggiero, Esq.;Ohlandt, Greeley, Ruggiero & Perle, L.L.P., 10th Floor, One Landmark Square, Stamford, CT, 06901-2682, US

(73) Assignee: KABUSHIKI KAISHA TOSHIBA

(21) Appl. No.: 12/050,089

(22) Filed: Mar. 17, 2008

(30) Foreign Application Priority Data
Mar. 28, 2007 (JP) 2007-086045

(51) Int. Cl. H01L 33/00

(52) U.S. Cl. 257/98; 257/E33.061

(57) ABSTRACT

A semiconductor light-emitting device includes a semiconductor light-emitting element which is capable of emitting light, a fluorescent substance which is capable of absorbing at least part of light emitted from the semiconductor light-emitting element and also capable of subsequently converting the wavelength of the absorbed light and emitting the light having a converted wavelength, and a light-transmissive sealing material encapsulating the semiconductor light-emitting element, formed of an inorganic material having, at least partially, a silicon-nitrogen linkage and including a fluorescent substance.

### CROSS-REFERENCE TO RELATED APPLICATIONS

This application is based upon and claims the benefit of priority from prior Japanese Patent Application No. 2007-086045, filed Mar. 28, 2007, the entire contents of which are incorporated herein by reference.

### BACKGROUND OF THE INVENTION

1. Field of the Invention

This invention relates to a semiconductor light-emitting device which can be used as a light source for various kinds of illumination such, for example, as the backlight for the display of personal computer and the illuminating light for a portable camera.

2. Description of the Related Art

Generally, a light-emitting diode chip for use in a semiconductor light-emitting device is designed to be encapsulated with a sealing resin. However, it is well known that when this sealing resin is irradiated with ultraviolet rays, etc., the optical characteristics as well as chemical characteristics thereof are caused to deteriorate. For example, since a GaN-based or InGaN-based blue light-emitting diode chip is provided, in addition to a visible light-emitting component, with a light-emitting component which is capable of emitting the light of ultraviolet wavelength region having a wavelength of not more than 380 nm, the sealing resin is gradually brought into yellowing starting from the peripheral portion of the light-emitting diode chip where the intensity of light to be irradiated would become stronger. Due to the sealing resin (yellowed resin) thus turned into yellow, the visible light to be emitted from the light-emitting diode chip is absorbed by the resin, thus causing the visible light to attenuate in intensity. Furthermore, due to the degradation of the sealing resin, the moisture vapor resistance of the sealing resin may be deteriorated and, at the same time, the ion permeability of the sealing resin may be increased. As a result, due to the ionic pollutants which are permitted to enter into the sealing resin from the outside, the light-emitting diode chip itself is caused to deteriorate, synergistically resulting in the deterioration of the emission intensity of semiconductor light-emitting device.

In the case of a GaN-based or InGaN-based blue light-emitting diode chip exhibiting a high forward voltage, a large magnitude of power loss is caused to occur even if the forward current passing therethrough is relatively low, thus causing the light-emitting diode chip to generate heat during the operation thereof. Due to this heat thus generated, the resin is heated, thus gradually deteriorating the resin and resulting in the yellowing of the resin.

In view of the facts that the sealing resin can be degraded within a short period of time as it is irradiated with ultraviolet rays and the semiconductor light-emitting device encapsulated with the sealing resin is caused to deteriorate in emission efficiency, there has been proposed, as one of countermeasures, to adopt a hermetic seal structure for the semiconductor light-emitting device as described, for example, in JP-A 10-242336 (KOKAI). According to this hermetic seal structure, a semiconductor light-emitting device is hermetically sealed in an outer casing and completely isolated from the external atmosphere, and the space inside the outer casing is filled with an inert gas such as nitrogen or with a stable sealing gas.

The conventional hermetic seal structure is however accompanied with problems that, since it requires expensive materials and also the manufacturing process thereof is relatively complicated, the final product would become expensive. Further, since the hermetic seal structure is designed such that the outer casing thereof is filled with an inert gas having a refractive index which differs greatly from the refractive index of a gallium nitride-based compound semiconductor, a reflecting surface is caused to be formed at an interface between the gallium nitride-based compound semiconductor and the inert gas. Because of this, the light to be emitted from the light-emitting diode chip is permitted to repeatedly reflect at the interface between the gallium nitride-based compound semiconductor and the inert gas, resulting in the attenuation of light, thereby deteriorating the emission efficiency of the semiconductor light-emitting device.

### BRIEF SUMMARY OF THE INVENTION

An object of the present invention is to provide a semiconductor light-emitting device which is excellent in environmental resistance such as ultraviolet light resistance, moisture absorption resistance and heat resistance.

It has been intensively studied by the present inventors to develop a semiconductor light-emitting device wherein a light-emitting diode chip is enveloped with a resin containing a fluorescent substance to form an encapsulated body which is further enveloped with a sealing resin, thereby enabling the light being released to the outside to be converted into a light of desired wavelength. By the way, the idea to envelope a light-emitting diode chip with a resin containing a fluorescent substance is accompanied, in practical viewpoint, with various problems as explained below.

First of all, if the environmental resistance of sealing resin is not necessarily sufficient, the fluorescent substance to be incorporated into the resin will be limited to only specific kinds. There is a problem in the application of calcium sulfide-based fluorescent substance, i.e. a representative known compound that can be hydrolyzed by water content, to the conventional light-emitting diode device.

Secondly, not only water content but also impurity ions such as sodium ion and chlorine ion are permitted to permeate into the fluorescent substance-containing resin, thereby giving harmful influence to the light-emitting diode chip. Accordingly, even with a light-emitting diode device which has been manufactured in a clean environment, there is a problem that impurity ions are permitted to permeate gradually into the interior of fluorescent substance-containing resin as the light-emitting diode device is left in an atmosphere containing the impurity ions, thereby deteriorating the electric properties of the light-emitting diode device. Especially serious problem is that there are not a few organic fluorescent substances which are chemically instable in the sense that harmful impurity ions are permitted to be liberated therefrom. Therefore, an organic fluorescent substance of this kind cannot be applied to the conventional semiconductor light-emitting device.

Due to various problems as described above in the case when a fluorescent substance is incorporated into a resin to be employed in the conventional semiconductor light-emitting device, there are possibilities of inviting the deterioration of reliability, the imperfection of light conversion function and the rise of product price. Accordingly, the present invention has been accomplished as described below as a result of profound studies made by the present inventors in an attempt to overcome the aforementioned problems.

Namely, the semiconductor light-emitting device according to the present invention is characterized in that it comprises a semiconductor light-emitting element which is capable of emitting light, a fluorescent substance which is capable of absorbing at least part of light emitted from the semiconductor light-emitting element and also capable of subsequently converting the wavelength of the absorbed light and emitting the light having a converted wavelength, and a light-transmissive sealing material encapsulating the semiconductor light-emitting element, formed of an inorganic material having, at least partially, a silicon-nitrogen linkage and containing the fluorescent substance.

### BRIEF DESCRIPTION OF THE SEVERAL VIEWS OF THE DRAWING

FIG. 1 is a cross-sectional view schematically illustrating a semiconductor light-emitting device according to the present invention, which is applied to a light-emitting diode device;

FIG. 2 is an enlarged cross-sectional view of a semiconductor light-emitting element;

FIG. 3 is a diagram for illustrating the principle of creating white color;

FIG. 4A is a diagram illustrating the chemical structure of polysilazane to be employed for creating a precursor;

FIG. 4B is a diagram illustrating the chemical structure of an inorganic material constituting a sealing material; and

FIG. 5 is a cross-sectional view schematically illustrating a light-emitting diode device according to the prior art.

### DETAILED DESCRIPTION OF THE INVENTION

The sealing material for the device of the present invention is formed of a light-transmissive inorganic material having, at least partially, a silicon-nitrogen linkage. As for specific examples of the inorganic material, it is preferable to employ light-transmissive (preferable transparent) ceramics, or high-purity glass such, for example, as quartz glass, soda glass or crystal glass. Among them, quartz glass is most preferable.

This high-purity glass sealing material can be manufactured by making use of a polysilazane method as described below.

This polysilazane method is a method for obtaining quartz glass by way of a de-ammonia reaction wherein polysilazane (—SiH₂NH—), which is a precursor having a silicon-nitrogen linkage, is sintered by heating it to a temperature of not lower than room temperature, thereby obtaining quartz glass. More specifically, the high-purity glass sealing material can be manufactured according to the following steps. At first, suitable quantities of a solvent and a fluorescent substance are added to polysilazane to create a solution of polysilazane having a prescribed concentration (viscosity). This fluorescent substance-containing solution is coated on the emission surface of semiconductor light-emitting element (which is soldered to a mount portion) to a desired thickness. The resultant coated layer is then sintered under predetermined conditions to obtain a transparent glass coating layer having a desired thickness. Alternatively, a suitable quantity of water may be added to polysilazane (—SiH₂NH—) to create a solution of polysilazane having a prescribed concentration (viscosity). The resultant solution is poured into a recessed portion in the mount portion to such an extent that the semiconductor light-emitting element disposed on the mount portion can be completely buried by the solution. The solution thus poured is then sintered under predetermined conditions to form a sealing material layer having a desired thickness. By controlling various conditions such as sintering temperature, sintering time, heating rate, the rate of temperature decrease, etc., it is possible to enable a suitable number of silicon-nitrogen linkages to leave in the transparent glass layer acting as a sealing material. By the way, the silicon-nitrogen linkages to be left in the sealing material may contain a dangling bond.

The sealing material is employed not only for sealing a semiconductor light-emitting element but also for holding a fluorescent substance having wavelength conversion capabilities. As for preferable examples of the fluorescent substance, it is possible to employ 3Sr₃(PO₄)₂.SrF₂:Sn²⁺,Mn²⁺, (Zn,Be)₂.SiO₄:Mn²⁺ or YAG-based ((Y,Gd)₃.Al₅O₁₂):Ce³⁺. It is more preferable to employ YAG-based ((Y,Gd)₃.Al₅O₁₂):Ce³⁺. In the employment of the fluorescent substance, although it is important how to combine it with the semiconductor light-emitting element in view of the function thereof to convert the wavelength of light, it is also important how to combine the resin-sealing material in order to suppress the deterioration of the resin-sealing material that may be caused to occur due to the irradiation of light.

In the embodiments of the present invention, since the sealing material is formed of an inorganic material such as high-impurity glass as described above, the impurities included in the sealing material can be confined to very small quantity as compared with low-melting glass containing boron or lead oxide, thereby making it possible to prevent the properties of semiconductor light-emitting element from being badly affected. Further, since the sealing material is in a state of glass exhibiting high heat resistance, it is possible to obviate the deterioration of light transmission properties that may be caused to occur due to the yellowing thereof.

An inorganic material such as high-purity glass would not be degraded even if it is exposed to the irradiation of the light of short wavelength such as ultraviolet rays under a high-temperature environment for a long period of time. When ultraviolet ray resistance is taken notice of, inorganic materials are far excellent as compared with organic resins. Further, even when moisture vapor resistance and heat resistance are taken notice of, inorganic materials are lower in changes with time and more stable in properties as compared with organic resins.

Next, best mode for carrying out the present invention will be explained with reference to drawings attached herewith. In this embodiment, one embodiment where the present invention is applied to a light-emitting diode device constituted by a gallium nitride-based compound is explained.

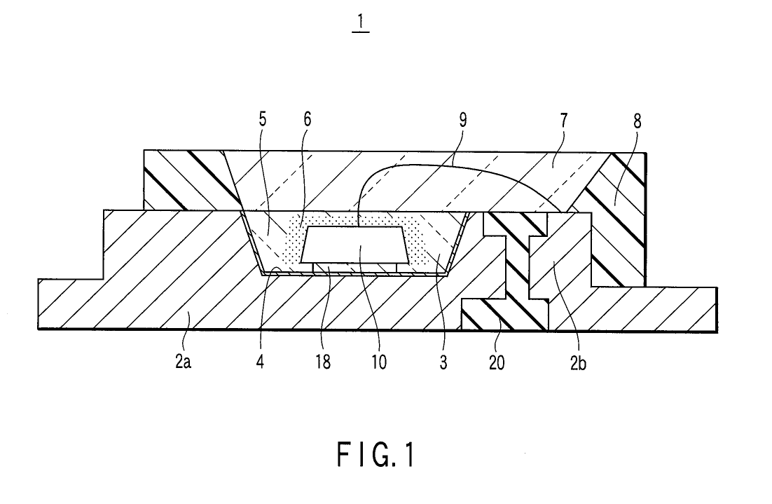

As shown in FIG. 1, the semiconductor light-emitting device 1 is provided, on Cu frames 2a, 2b employed respectively as a conductive substrate, with a vitreous sealing material 5 including fluorescent substances 6, with a covering resin sealing material 7, with a resin frame 8 and with an LED chip 10 acting as a semiconductor light-emitting element. The Cu frame 2a is provided with a recessed portion to be employed as a mount portion 3. The LED chip 10 is bonded to an approximately central portion of the mount portion 3 by means of an Au-system solder-bonding portion 18. By the way, a reference number 20 represents an insulating body insulating the Cu frame 2a of negative electrode side from the Cu frame 2b of positive electrode side.

The LED chip 10 can be bonded to the mount portion 3 in a manner explained below. By making use of known plating method, an Ag-plating layer 4 is deposited, as an underlying conductive layer, on the mount portion 3. Then, by making use of an Au-system soldering material (for example, an Au—Sn solder alloy), the negative electrode side of the LED chip 10 is soldered to mount portion 3. By doing so, the negative electrode side of the LED chip 10 is electrically connected with a terminal (not shown) of the negative electrode.

The mount portion 3 is filled with the sealing material 5 formed of an inorganic material having, at least partially, a silicon-nitrogen linkage. The LED chip 10 is completely buried in the sealing material 5. The sealing material 5 includes therein particles of fluorescent substance 6. This fluorescent substance 6 is formed of YAG-based ((Y,Gd)₃.Al₅O₁₂):Ce³⁺ and the particles of fluorescent substance 6 are dispersed in the vicinity of the light-emitting face of LED chip 10.

The resin frame 8 is attached to the Cu frames 2a, 2b so as to cover the light-emitting face of the light-emitting device 1. The recessed portion of the resin frame 8 is filled with the covering resin sealing material 7. This covering resin sealing material 7 is disposed so as to entirely cover the surface of sealing material 5 of the mount portion 3. The light emitted from the LED chip 10 is converted into one having desired wavelength by the presence of the sealing material 5 including the fluorescent substance 6 and then permitted to pass through the covering resin sealing material 7 before being emitted outside from the light-emitting device 1. By the way, the resin frame 8 is formed of transparent resin (for example, epoxy resin). On the top of the covering resin sealing material 7 is disposed a lens portion (not shown) for converging the light that has been emitted from the LED chip 10 or the light reflected by the surface of mounting portion 3.

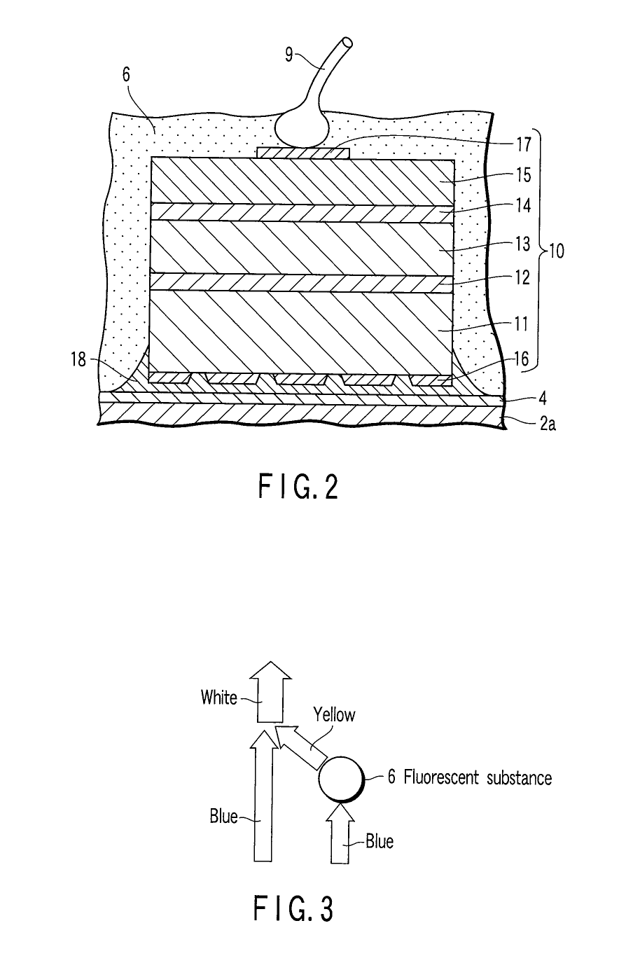

FIG. 2 shows an enlarged view of the LED chip 10. The construction of the LED chip 10 will be explained with reference to FIG. 2. As shown in FIG. 2, the n-side (negative) electrode 16 of the LED chip 10 is electrically connected with a terminal of negative electrode via the Au-system solder-bonding portion 18, the Ag-plating layer 4 and the Cu frame 2a. On the other hand, the p-side (positive) electrode 17 of the LED chip 10 is electrically connected, by means of an Au wiring 9 that has been wire-bonded and via the Cu frame 2b (not shown), with a terminal of positive electrode.

The LED chip 10 is constituted by an n-type SiC substrate 11 and a laminate which is deposited on the substrate 11 and composed of a buffering layer 12, an n-type GaN clad layer 13, an InGaN/GaN active layer 14 and a p-type GaN clad layer 15, which are laminated in the mentioned order. An n-type anode 16 is disposed on the underside of the n-type SiC substrate 11 and a p-type cathode 17 is disposed on the upper surface of the p-type GaN clad layer 15. The n-type anode 16 is electrically connected, via the conductive solder-bonding portion 18 and the Ag-plating layer 4, with the Cu frame 2a. Further, the cathode 17 is electrically connected, via the Au wiring 9, with the other Cu frame 2b. When a predetermined electric current is passed between these electrodes 16 and 17, a colored light (for example, blue light) having a specific wavelength is emitted from the light-emitting face of LED chip 10.

In the fabrication of the LED chip 10, it is possible to employ a gallium nitride-based compound semiconductor which is capable of emitting a light having a wavelength ranging from 300 to 550 nm. In this embodiment, an InGaN-based blue light-emitting diode chip with a peak of light-emitting wavelength falling within the range of 380 nm-420 nm was employed in the LED chip 10. By the way, it is also possible to employ a GaN-based blue light-emitting diode chip with a peak of light-emitting wavelength falling within the range of 440 nm-470 nm.

The gallium nitride-based compound semiconductor can be represented by a chemical formula: In_{(1-X)}Ga_{X}N (wherein 0<x≦1) and can be formed by means of any known epitaxial growth method on the surface of an insulating substrate constituted, for example, by a sapphire base body.

In the case of the semiconductor light-emitting device 1, the upper surface and sidewalls of the LED chip 10 are covered by the sealing material 5. This sealing material 5 can be created by making use of a sealing material-producing solution containing polysilazane in its starting raw material (precursor). This sealing material-producing solution is excellent in ultraviolet resisting properties and heat resistance and can be prevented from being substantially degraded (yellowing, moisture absorption, thermal degradation, etc.) even if it is left under high-temperature environments or under the irradiation of ultraviolet rays. Because of this, since the sealing material 5 is chemically stable, even if the sealing material 5 is exposed to the irradiation of the light of short wavelength from the LED chip 10 for a relatively long time, the sealing material 5 can be prevented from being degraded to such an extent that may attenuate the emission of light from the LED chip 10. Further, even if temperature rise is caused to occur in the sealing material 5 due to the heat developed in the LED chip 10, the sealing material 5 can be prevented from being degraded to such an extent that may attenuate the emission of light from the LED chip 10.

Although the covering resin sealing material 7 is formed of epoxy-based resin which is not so excellent in ultraviolet resisting properties, the degradation of covering resin sealing material 7 by ultraviolet rays can be effectively prevented owing to the presence of the sealing material 5 which is excellent in ultraviolet resisting properties and interposed between the covering resin sealing material 7 and the LED chip 10.

Although the sealing material-producing solution for creating the sealing material 5 is liquid ordinarily, when it is heated in air atmosphere or in an oxygen-containing atmosphere, a transparent sealing material comprising, as a major component, silazane linkage of metal oxide is created due to the decomposition of components or the absorption of oxygen. This sealing material-producing solution is then mixed with the powder of fluorescent substance 6 and coated on the outer wall of the semiconductor light-emitting element, thereby making it possible to create the sealing material 5 including the fluorescent substance 6.

In this semiconductor light-emitting device 1, the LED chip 10 is fixedly secured to the recessed portion 3 and covered not only with the sealing material 5 including the fluorescent substance 6 but also with the covering resin sealing material 7. On the occasion of manufacturing the semiconductor light-emitting device 1, the sealing material-producing solution containing the fluorescent substance 6 is poured into the recessed portion 3 from a position over the LED chip 10 and then subjected to sintering at a temperature ranging from about 150° C. to 200° C. to thereby solidify the sealing material 5 including the fluorescent substance 6. Thereafter, an end portion of the external terminal is entirely sealed with a transparent sealing resin. The sintering temperature of the sealing material 5 should be sufficiently lower than the melting point of the light-emitting diode chip-bonding portion 18, more preferably be confined to the range of 175° C.-185° C. When the sealing material 5 is sintered within this range of temperature, the sealing material is enabled to have a desired mechanical strength and, at the same time, the peripheral instruments can be prevented from being badly affected by the sealing resin.

In order to further improve the optical properties and workability of the semiconductor light-emitting device, various modifications can be made according to the present invention. By making use of a sealing material 5 comprising inorganic materials, various weak points of the conventional semiconductor light-emitting device can be overcome, thereby making it possible to obtain a semiconductor light-emitting device which can be manufactured at a low cost and is high in reliability.

The fluorescent substance 6 should preferably be natured such that the light of specific wavelength which will be emitted from the LED chip 10 can be easily absorbed therein. For example, the fluorescent substance 6 may be formed by making use of YAG-based ((Y,Gd)₃.Al₅O₁₂):Ce³⁺, 3Sr₃(PO₄)₂.SrF₂:Sn²⁺,Mn²⁺ or (Zn,Be)₂.SiO₄:Mn²⁺, all of which being capable of absorbing blue light and converting it in wavelength to create yellow light.

When the LED chip 10 is formed of In_{0.2}Ga_{0.8}N (465 nm; blue), the fluorescent substance 6 should preferably be formed by making use of YAG-based ((Y,Gd)₃.A₅O₁₂):Ce³⁺. Further, when the LED chip 10 is formed of In_{0.10}Ga_{0.90}N (405 nm; bluish purple), the fluorescent substance 6 should preferably be formed by making use of ZnS:Cu,Al or MgAl₁₀O₁₇:Eu,Mn. Furthermore, when the LED chip 10 is formed of In_{0.45}Ga_{0.55}N (465 nm; green), the fluorescent substance 6 should preferably be formed by making use of Y₂O₂S:Eu.

The inorganic material to be employed for the sealing material should preferably be formed of ceramics that can be manufactured by making use of a precursor having silicon-nitrogen linkage. Especially, the employment of a solution containing polysilazane is preferable in the manufacture of the precursor. Since an organic material such as resin is permeable to water and to impurity ions such as sodium and chlorine giving harmful influence to the light-emitting diode chip, the organic material is unsuitable for use in the sealing material.

In the vicinity of the light-emitting face of LED chip 10, particles of the fluorescent substance 6 are dispersed in the sealing material 5. The dispersion density of particles of fluorescent substance 6 should preferably be confined to 100 mg/cm³.

The semiconductor light-emitting device according to this embodiment is capable of generating white light. The principle of this emission will be explained with reference to FIG. 3. A portion of blue light emitted from the LED is absorbed by the fluorescent substance 6 and converted in wavelength to give yellow light, which is then mixed with blue light that has not been converted in wavelength, thus giving pseudo-white light. Although this pseudo-white light is slightly bluish, it may be said as being substantially white light. Further, this pseudo-white light can be hardly deteriorated in light intensity (brightness).

Next, Examples of the present invention will be explained in comparison with Comparative Example.

### EXAMPLE 1

In this Example 1, a glass sealing material containing fluorescent substance was manufactured by making use of polysilazane method.

By following the polysilazane method, polysilazane (SiH₂NH—) was dissolved in a xylene solvent to obtain a solution. To 10 ml of this solution, a suitable quantity of water was dropped to obtain an aqueous solution, which was then coated on the light-emitting face of LED and sintered for a prescribed period of time at a temperature of about 180° C.

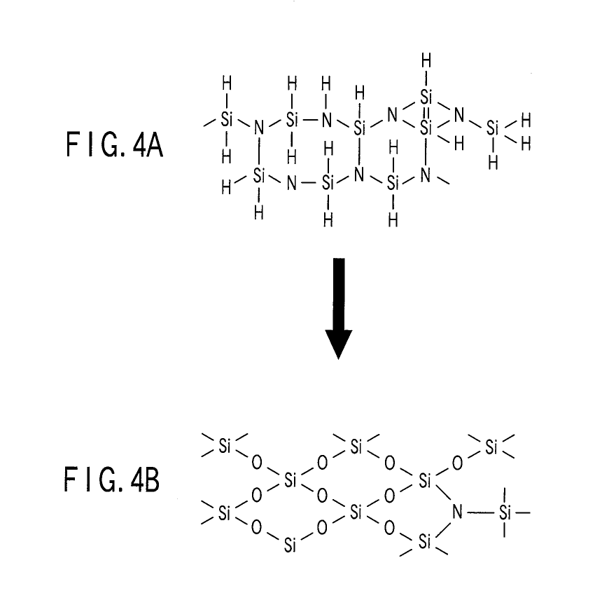

FIG. 4A is a diagram illustrating the chemical structure of polysilazane to be employed for creating the precursor. The polysilazane which is useful as the precursor has Si—N linkage in a portion of the chemical structure thereof. FIG. 4B shows the chemical structure of an inorganic material constituting the sealing material. Even in the inorganic material constituting the sealing material that had been sintered, the Si—N linkage was retained in a portion of the chemical structure thereof. This Si—N linkage may contain, though very few, a dangling bond. It was confirmed by means of X-ray absorption fine structure (XAFS) measuring method that the dangling bond was formed of an Si—N structure.

### COMPARATIVE EXAMPLE 1

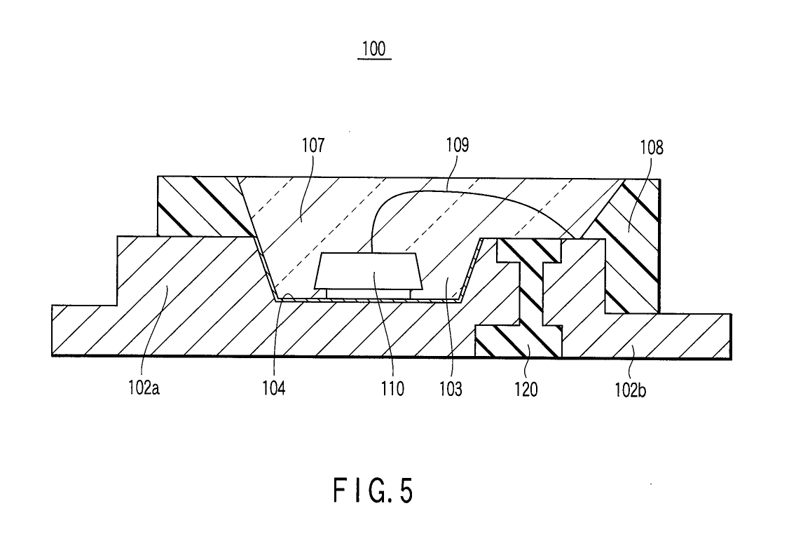

As Comparative Example 1, the conventional semiconductor light-emitting device 100 as shown in FIG. 5 was manufactured.

The outline of the conventional semiconductor light-emitting device will be explained with reference to FIG. 5. The semiconductor light-emitting device 100 is provided, on Cu frames 102a, 102b employed respectively as a conductive substrate, with a covering resin sealing material 107, a resin frame 108 and an LED chip 110. The Cu frame 102a is provided with a recessed portion to be employed as a mount portion 103. The LED chip 110 is soldered to Ag-plating layer 104 at an approximately central portion of the mount portion 103. The covering resin sealing material 107 includes powders of fluorescent substance (not shown). By the way, a reference number 120 represents an insulating body insulating the Cu frame 102a of negative electrode side from the Cu frame 102b of positive electrode side.

The n-side (negative) electrode of the LED chip 110 is electrically connected with a terminal of negative electrode (not shown) via the Au-based solder-bonding portion, the Ag-plating layer 104 and the Cu frame 102a. On the other hand, the p-side (positive) electrode of the LED chip 110 is electrically connected, by means of an Au wiring 109 that has been wire-bonded and via the Cu frame 102b, with a terminal of positive electrode (not shown).

When an electric current is passed, through the Cu frame 102b and the Au wiring 109, to the light-emitting diode (LED) chip 110 by applying a voltage between the positive terminal and the negative terminal of the semiconductor light-emitting device 100, light is emitted from the LED chip 110 and released outside of the semiconductor light-emitting device 100 after passing through the sealing resin 107. The light emitted from the LED chip 110 is converted into a different wavelength depending on the kinds of fluorescent substance (not shown) that has been mixed into the sealing resin 107 before it is released to the outside thereof. As a result, light having a different wavelength from that of the light emitted from the LED chip 110 can be released. Namely, the sealing resin 107 is caused to gradually become yellow starting from the peripheral portion of the light-emitting diode chip where the intensity of light to be irradiated would become stronger. Due to the yellowed sealing resin, the visible light emitted from the light-emitting diode chip 110 is absorbed by the yellowed sealing resin 107, thus attenuating the intensity thereof.

Furthermore, due to the degradation of the sealing resin 107, the moisture vapor resistance thereof is deteriorated and, at the same time, the ion permeability of the sealing resin is increased. As a result, due to the ionic pollutants which are permitted to enter into the sealing resin from the outside, the LED chip 110 itself is caused to deteriorate, synergistically resulting in the deterioration of the emission intensity of semiconductor light-emitting device 100.

In the case of an InGaN-based LED chip exhibiting a high forward voltage, a large magnitude of power loss is caused to occur even if the forward current passing therethrough is relatively low, thus causing the LED chip to generate heat during the operation thereof. The resin 107 thus heated is gradually caused to degrade, resulting in the yellowing of the resin 107.

(Assessment)

The illumination properties of the samples of semiconductor light-emitting devices of Example 1 and Comparative Example 1 were assessed based on the emission efficiency. The emission efficiency herein indicates the conversion ratio in the conversion of electricity into light. The higher the conversion ratio is, the more excellent is the performance of light-emitting device. As a result of this comparison, the devices of Example 1 was found twice as excellent in emission efficiency as Comparative Example 1.

The semiconductor light-emitting device of the present invention is excellent in environmental resistance such as ultraviolet light resistance, moisture absorption resistance and heat resistance. According to the semiconductor light-emitting device of the present invention, it is possible to suppress the degradation of sealing material and to prevent the permeation of harmful substances, thereby making it possible to obtain a semiconductor light-emitting device which is excellent in reliability and in light-retrieving efficiency. According to the present invention, since a semiconductor light-emitting element having a large energy gap is employed, it is now possible to realize a semiconductor light-emitting device which is capable of emitting light having a wavelength ranging from visible light to ultraviolet ray region which is relatively short in wavelength. A nitrogen-gallium-based compound semiconductor such as GaN, GaAlN, InGaN, InGaAlN, etc. can be utilized, as a semiconductor light-emitting element for emitting the light of this wavelength range, for the fabrication of a novel solidified ultraviolet light source having various advantages such as small in size, low in power consumption, long in life, etc.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor light-emitting device comprising:
a semiconductor light-emitting element which is capable of emitting light;
a fluorescent substance which is capable of absorbing at least part of light emitted from the semiconductor light-emitting element and also capable of subsequently converting the wavelength of the absorbed light and emitting the light having a converted wavelength; and
a light-transmissive sealing material encapsulating the semiconductor light-emitting element, formed of an inorganic material having, at least partially, a silicon-nitrogen linkage and including the fluorescent substance.

2. The device according to claim 1, wherein the inorganic material is formed of ceramics which can be manufactured by making use of a precursor having silicon-nitrogen linkage and wherein the silicon-nitrogen linkage of the precursor is partially left remained therein after the manufacture thereof.

3. The device according to claim 2, wherein the precursor comprises polysilazane.

4. The device according to claim 1, wherein the semiconductor light-emitting element is a gallium nitride-system blue light-emitting element.

5. The device according to claim 1, wherein the semiconductor light-emitting element is capable of emitting blue light and the fluorescent substance is capable of converting, with respect to wavelength, part of blue light to be emitted from the semiconductor light-emitting element, thereby enabling it to release yellow light.

6. The device according to claim 5, wherein the yellow light obtained from the conversion in wavelength of part of blue light is mixed with the balance of blue light, enabling the device to emit pseudo-white light.
